(19) United States
(12) Patent Application Publication
(10) Pub. No.: US 2025/0306473 A1
(43) Pub. Date: Oct. 2, 2025

(54) EXPOSURE APPARATUS, METHOD OF CONTROLLING EXPOSURE APPARATUS, AND METHOD OF MANUFACTURING PRODUCT

(71) Applicant: CANON KABUSHIKI KAISHA, Tokyo (JP)

(72) Inventors: HIROKI TAKADA, Saitama (JP); TSUBASA NOSE, Tochigi (JP)

(21) Appl. No.: 19/082,370

(22) Filed: Mar. 18, 2025

(30) Foreign Application Priority Data
Mar. 28, 2024 (JP) 2024-053419

(51) Int. Cl. G03F 7/00

(52) U.S. Cl. CPC G03F 7/70525; G03F 7/70191; G03F 7/70508; G03F 7/70575

(57) ABSTRACT

An exposure apparatus includes: an illumination optical system including a plurality of optical elements changing a wavelength band of light from a light source and configured to illuminate an illuminated surface with light of which a wavelength band has been changed by one of the plurality of optical elements; and a control unit configured to control input power to the light source using a correction value corresponding to a relation of a change in illuminance to the input power to the light source to maintain constant illuminance on the illuminated surface. The control unit uses different correction values for the plurality of optical elements.

### BACKGROUND

### Technical Field

The present disclosure relates to an exposure apparatus, a method of controlling the exposure apparatus, and a method of manufacturing a product.

### Description of the Related Art

Exposure apparatuses can be used for lithography processes of manufacturing products such as semiconductor devices. An exposure apparatus includes an illumination optical system that illuminates an original plate and a projection optical system that projects a pattern of the illuminated original plate onto a substrate. The substrate has a photoresist on its surface, and thus the pattern is transferred to the photoresist by projecting the pattern of the original plate to the substrate.

As a light source of the illumination optical system, for example, a mercury lamp is used. By changing input power of the mercury lamp, it is possible to change an optical output of the mercury lamp. However, since the mercury lamp deteriorates over time, the optical output cannot be maintained to be constant even when the same power is input. Accordingly, as known from Japanese Patent Application Laid-open No. H6-36984, a constant optical output of a light source can be maintained and a constant illuminance of the illumination optical system is maintained by adjusting the input power whenever a given period has passed. This function is also referred to as a constant illuminance function.

For the constant illuminance function, it is necessary to measure a relation between input power and an optical output of a mercury lamp in advance. Since the optical output of the mercury lamp changes substantially proportionally to the input power, an approximation coefficient measured in advance is used. The optical output and the input power can be expressed as optical output=approximation coefficient×input power using the approximation coefficient. Here, the approximation coefficient is expressed as a first-order approximation coefficient, but may be obtained as a polynomial approximation coefficient.

In an illumination optical system, a wavelength filter is used as an optical element that passes only a specific wavelength band. A mercury lamp used for the illumination optical system emits light with a certain wavelength band around a central emission wavelength. In this way, a light quantity distribution of a wavelength band in which a mercury lamp emits light is referred to as a light emission spectrum. A wavelength filter is used to cut a specific wavelength band from a light emission spectrum of a mercury lamp. In general, when a wavelength filter with a narrow band is used, an influence of chromatic aberration of a projection optical system can be curbed. Therefore, an improvement in image performance can be expected. Conversely, when a wavelength filter with a broad band is used, an amount of combined light increases. Therefore, an increase in illuminance of an illuminated surface can be expected. Since an exposure apparatus is used for various processes, a plurality of wavelength filters is mounted inside the exposure apparatus so that a wavelength filter can be switched for exposure in accordance with a process.

However, a light emission spectrum of a mercury lamp is changed in accordance with input power. Therefore, an amount of change of optical output relative to the input power of the mercury lamp differs depending on a wavelength band cut by a wavelength filter. In a constant illuminance function of the related art, an approximation coefficient used to calculate a power adjustment amount was not separated for each wavelength filter to be used. Therefore, the constant illuminance function can be applied using an optimum approximation coefficient for a certain specific wavelength filter. However, when the wavelength filter is switched, an error of the approximation coefficient occurs, which makes it difficult to maintain ideal constant illuminance.

### SUMMARY

Accordingly, according to an embodiment of the present invention, an optimum constant illuminance function appropriate for a wavelength band is realized.

According to an aspect of the present invention, an exposure apparatus includes: an illumination optical system including a plurality of optical elements changing a wavelength band of light from a light source and configured to illuminate an illuminated surface with light of which a wavelength band has been changed by one of the plurality of optical elements; and a control unit configured to control input power to the light source using a correction value corresponding to a relation of a change in illuminance to the input power to the light source to maintain constant illuminance on the illuminated surface.

The control unit uses different correction values for the plurality of optical elements. Further features of the present invention will become apparent from the following description of exemplary embodiments with reference to the attached drawings.

### BRIEF DESCRIPTION OF THE DRAWINGS

FIG. 1 is a schematic view illustrating a configuration of an exposure apparatus according to a first embodiment.

FIGS. 2A and 2B are diagrams illustrating a change in a wavelength feature of a light source to input power to the light source according to the first embodiment.

FIG. 3 is a diagram illustrating a change in an optical output of the light source relative to the input power to the light source according to the first embodiment.

FIG. 4 is a flowchart illustrating a constant illuminance function according to the first embodiment.

FIG. 5 is a flowchart illustrating a precondition measurement of the constant illuminance function according to the first embodiment.

FIG. 6 is a flowchart illustrating calculation of a power adjustment amount according to the first embodiment.

FIG. 7 is a flowchart illustrating precondition measurement of a constant illuminance function according to a second embodiment.

FIG. 8 is a flowchart illustrating calculation of a power adjustment amount according to the second embodiment.

### DESCRIPTION OF THE EMBODIMENTS

Hereinafter, embodiments will be described in detail with reference to the appended drawings. The following embodiments do not limit the invention as disclosed in the claims. In the embodiments, a plurality of features will be described, but not all the plurality of features are necessarily essential to the invention and the plurality of features may be combined arbitrarily. Further, in the appended drawings, same or similar configurations are denoted by the same reference numerals and repeated description thereof will be omitted.

### First Embodiment

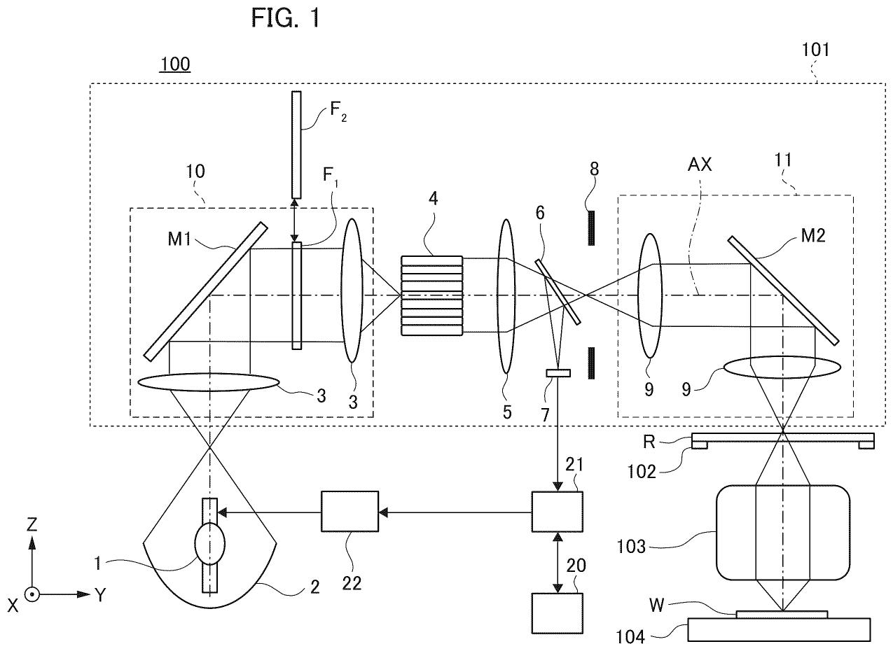

FIG. 1 is a schematic view illustrating a configuration of an exposure apparatus 100 according to a first embodiment. The exposure apparatus 100 is, for example, a lithography apparatus that forms a pattern on a substrate using a step of manufacturing a semiconductor device or the like (lithography step). The exposure apparatus 100 forms a latent image pattern in a pattern region of a substrate W by exposing the substrate W through an original plate (mask) R to transfer a pattern of the original plate to the substrate to which a resist (resin) is applied. In the present embodiment, the exposure apparatus 100 is a step-and-repeat type exposure apparatus (stepper) that collectively exposes the substrate W through the original plate R. Here, the step-and-repeat type exposure apparatus 100 or another type exposure apparatus can also be adopted.

The exposure apparatus 100 includes an illumination optical system 101, an original plate driving unit 102, a projection optical system 103, a substrate driving unit 104, a storage unit 20, a control unit 21, a power unit 22, a light source 1, and an elliptical mirror 2. In the present embodiment, a coordinate system in which an axis oriented in a normal direction of the substrate W is referred to as the Z axis and axes oriented in directions orthogonal to each other in a plane parallel to the substrate W are the X and Y axes is defined. In the drawing, AX denotes an optical axis.

The illumination optical system 101 illuminates the original plate R disposed on an illuminated surface (an object surface of the projection optical system 103) using light (light flux) from the light source 1. The light source 1 includes, for example, a super-high pressure mercury lamp that emits light such as an i-line (with a wavelength of 365 nm). However, the light source 1 is not limited thereto and may be a KrF excimer laser that emits light with a wavelength of 248 nm, an ArF excimer laser that emits light with a wavelength of 193 nm, or an F2 laser that emits light with a wavelength of 157 nm. The light source 1 may be an EUV light source that emits extreme ultraviolet light (EUV light) with a wavelength of about 11 nm to 14 nm. The light source 1 emits light of an output in accordance with input power from the power unit 22.

On the original plate R, a pattern (for example, a circuit pattern) to be transferred to the substrate W is formed. The original plate R is formed of a material transmitting light from the light source 1 (the illumination optical system 101), for example, quartz glass serving as a base material. The original plate driving unit 102 includes, for example, a movable original plate stage that holds the original plate R and an original plate driving mechanism that drives the original plate stage along the X and Z axes.

The projection optical system 103 projects the pattern of the original plate R irradiated by the illumination optical system 101 to the substrate W. The projection optical system 103 includes an imaging optical system. A front-side focal point is disposed on a surface (position) on which the original plate R is disposed and a rear-side focal point is disposed on a surface on which the substrate W is disposed. In other words, the projection optical system 103 has a conjugate relation between a position at which the original plate R is disposed and a position at which the substrate W is disposed.

The substrate W is a substrate to which the pattern of the original plate R is transferred and a resist (photosensitive material) is supplied to the surface of the substrate. The substrate driving unit 104 includes a movable substrate stage that holds the substrate W and a substrate driving mechanism that drives the substrate stage along the X, Y, and Z axes (and rotational directions ωx, ωy, and ωz).

Hereinafter, the illumination optical system 101 will be described in detail. The illumination optical system 101 is an illumination mechanism that illuminates an illuminated surface with light from the light source 1. The illumination optical system 101 according to the present embodiment includes a first relay lens 3, a folding mirror M1, an optical integrator 4, a second condenser lens 5, an extraction mirror 6, an illuminometer 7, a field stop 8, an imaging lens 9, and a folding mirror M2.

The first relay lens 3 and the folding mirror M1 are included in the first illumination optical system 10. The imaging lens 9 and the folding mirror M2 are included in the imaging illumination optical system 11. Light from the first illumination optical system 10 is incident on the second condenser lens 5 via the optical integrator 4.

The elliptical mirror 2 has first and second focal points and condenses light from the light source 1 disposed at the first focal point on the second focal point. The first relay lens 3 includes an imaging optical system. The front-side focal point is disposed at the second focal point of the electrical mirror 2 and the rear-side focal point is disposed on an incidence surface of the optical integrator 4. In other words, the first relay lens 3 has a conjugate relation between the second focal point of the elliptical mirror 2 and the incidence surface of the optical integrator 4.

In this way, according to the present embodiment, the illumination optical system 101 includes the first illumination optical system 10 that has a conjugate relation between the second focal point of the elliptical mirror 2 and the incidence surface of the optical integrator 4. However, the present invention is not limited thereto and the first illumination optical system that does not have such a relation may be included.

A wavelength filter F₁ is disposed near a pupil surface of the first relay lens 3 as an optical element that transmits only light with a specific wavelength band, and an exposure wavelength (a wavelength of light for exposing the substrate W) is defined by the wavelength filter. In the embodiment, optical elements include two types of optical elements, that is, the wavelength filter F₁ that transmits a narrow wavelength band and a wavelength filter F₂ that transmits a broad wavelength band. Selection of a wavelength band appropriate for an exposure condition is achieved when the control unit 21 switches such a wavelength filter in accordance with the exposure condition. In other words, the wavelength filters F₁ and F₂ also function as optical elements that change a wavelength band of light from the light source 1. That is, the illumination optical system 101 according to the present embodiment illuminates an illuminated surface with light of which a wavelength band has been changed by any of a plurality of image sensors (the wavelength filters F₁ and F₂) disposed in the illumination optical system 101. The wavelength filters F₁ and F₂ have different approximation coefficients (correction values) to be described below. The approximation coefficient is a coefficient indicating a change in illuminance on the illuminated surface relative to the input power to the light source 1.

In the present embodiment, the above two types of wavelength filters are used, but the types of wavelength filters are not limited to the two types. The illumination optical system 101 may include two or more types of wavelength filters. In this way, in the present embodiment, when the control unit 21 switches the plurality of wavelength filters in accordance with a predetermined exposure condition, the wavelength filters F₁ and F₂ that are optical elements are positioned within the illumination optical system 101.

The optical integrator 4 is, for example, a fly's eye lens and is an element in which a plurality of minute lenses are arrayed 2-dimensionally in an incidence light direction to form a plurality of secondary light supplies. An incidence surface of each of the minute lenses of the optical integrator 4 has a conjugate relation with an illuminated surface. The fly's eye lens includes a cylindrical lens or a microlens array, and may be an optical rod or a diffractive optical element.

The second condenser lens 5 illuminates light emitted from each of the minute lenses of the optical integrator 4 onto the field stop 8 in a superimposition manner. The field stop 8 includes a plurality of movable light-shielding plates that form any aperture shape and limits an exposure range on a position at which the original plate that is an illuminated surface is disposed (further a position at which the substrate is disposed). The imaging lens 9 forms an image of the field stop 8 and the original plate R in the conjugate relation and illuminates the aperture shape defined by the field stop 8 onto the original plate R.

The extraction mirror 6 can reflect part of the light with which the field stop 8 is illuminated and the illuminometer 7 is disposed at an imaging position at which the light reflected by the extraction mirror 6 is reflected. The imaging position at which the illuminometer 7 is positioned is equivalent to the position of the field stop 8 that is an imaging position of the second condenser lens 5. Since the field stop 8 is conjugate to the original plate R, it is homonymous that the illuminometer 7 is observing illuminance on the original plate R. The control unit 21 receives an illuminance value measured by the illuminometer 7. The illuminance according to the present embodiment is illuminance on the illuminated surface and a surface at a position conjugate to the illuminated surface. The storage unit 20 is configured with an auxiliary storage device or the like such as a hard disk drive (HDD) or a solid state drive (SSD) and is a storage device that stores various types of setting data or data of various parameters. The storage unit 20 may be an optical disc such as a flexible disk (FD) or a compact disk (CD) that can be detachably mounted on the exposure apparatus 100, a magnetic or optical card, an IC card, a memory card, or the like.

The control unit 21 is configured as at least one computer that includes at least one CPU (processor) or one or plurality of memories. The control unit 21 is connected to each constituent element of the exposure apparatus 100 via a line. The memory is configured as a random access memory (RAM) and a read only memory (ROM). The RAM is a volatile memory. For example, an SRAM, a DRAM, or the like can be applied. The ROM is a nonvolatile memory. For example, an EEPROM, a flash memory, or the like can be applied. A program for realizing a function of the exposure apparatus 100 or data used to execute the program is stored in the ROM or the auxiliary storage device.

The program or each piece of data is loaded appropriately in the RAM by the control unit 21 to be executed. Accordingly, each constituent element of the exposure apparatus 100 functions. In this way, the control unit 21 generally controls an operation, adjustment, or the like of each constituent element of the entire exposure apparatus 100 in accordance with the program stored in the memory. The control unit 21 may be configured integrally with other portions of the exposure apparatus 100, may be configured separately from the other portions of the exposure apparatus 100, or may be positioned at a different location from the exposure apparatus 100 to be controlled remotely.

In a constant illuminance function of the related art, input power to the light source 1 necessary to maintain set illuminance is calculated from an illuminance value received by the control unit 21. An optical output of the light source 1 was set to any value by controlling the power unit 22 so that the calculated input power is achieved.

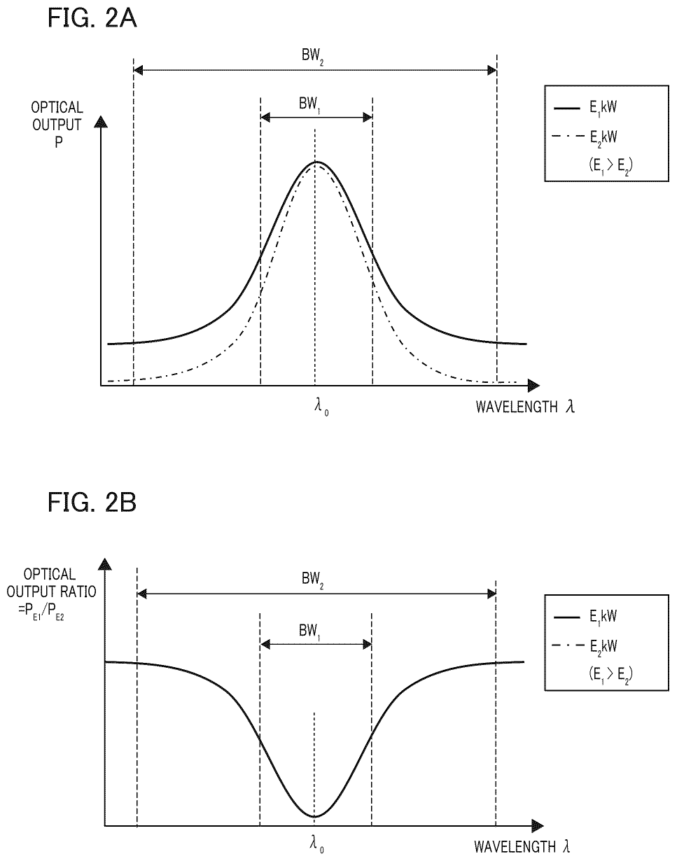

A relation between a light emission spectrum of the light source 1 and input power of the power unit 22 will be described with reference to FIGS. 2A and 2B. FIGS. 2A and 2B are diagrams illustrating a change in a wavelength feature of the light source 1 to the input power to the light source 1.

FIG. 2A is a diagram illustrating a change in the light emission spectrum of the light source 1. In FIG. 2A, the horizontal axis represents a wavelength λ and the vertical axis represents an optical output (illuminance) P at each wavelength. The light source 1 emits light with a certain wavelength band in which the optical output Pat a light emission center wavelength λ₀ is the highest and the light emission center wavelength λ₀ is a center. FIG. 2A illustrates, for example, a change in the light emission spectrum when input power to the light source 1 is changed to E₁ and E₂. E₁ and E₂ have a relation of E₁>E₂.

FIG. 2B is a diagram illustrating a result obtained by calculating an optical output ratio=P_{E1}/P_{E2} in input power E₁ and an input power E₂. As illustrated in FIG. 2B, a change in the light emission spectrum when the input power to the light source 1 is changed is not constant at each wavelength and an amount of change of the optical output P is larger in a surrounding wavelength band than in the light emission center wavelength λ₀.

In the present embodiment, it is assumed that BW₁ is a wavelength band transmitted by the wavelength filter F₁ and BW₂ is a wavelength band transmitted by the wavelength filter F₂. As illustrated in FIGS. 2A and 2B, the wavelength filters F₁ and F₂ have the same light emission center wavelength λ₀ of the cut wavelength band and different wavelength bands (BW₁ and BW₂) widths. That is, the wavelength filters F₁ and F₂ change the wavelength band of light from the light source 1 so that the wavelength band widths are different.

BW₁ and BW₂ have a relation of BW₁<BW₂. That is, the wavelength filter F₂ transmitting a broader band is further influenced by a surrounding wavelength band in which a change in the optical output P due to a change in power is large than the wavelength filter F1 transmitting only a wavelength band near the light emission center wavelength λ₀. Therefore, in the wavelength filter F₂ with a broad wavelength band, a change in the optical output P due to the change in power is large. In this way, since the light emission spectrum of the light source 1 is changed by the input power, the amount of change of the optical output differs for each wavelength filter to be used.

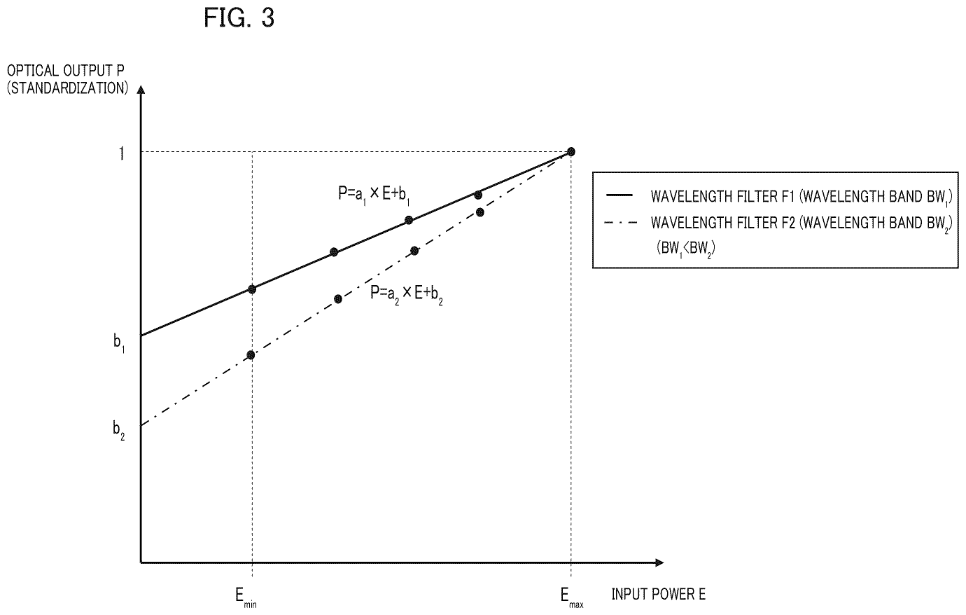

FIG. 3 is a diagram illustrating a change in the optical output P relative to the input power E to the light source 1 using the wavelength filters F₁ and F₂ with different wavelength bands (BW₁ and BW₂). Here, the optical output P is normalized with a value at the time of lighting at maximum input power Eₘₐₓ. A relation of the optical output P to the input power E is linearly approximated. An approximation coefficient for the wavelength filter F₁ is a₁·b₁ and an approximation coefficient for the wavelength filter F₂ is a₂·b₂. That is, the approximation coefficients are coefficients corresponding to a relation of a change in illuminance to the input power E to the light source 1 and are also correction values used for the control unit 21 to control the input power E to the light source 1, as will be described below. In the embodiment, the control unit 21 controls the input power E to the light source 1 using different correction values corresponding to a plurality of optical elements. The approximation coefficients may be obtained using a preset table or may be complemented and obtained from a relation of the change in illuminance to the input power E to the light source 1.

As illustrated in FIGS. 2A and 2B, when the light emission spectrum of the light source 1 is changed relative to the input power E, a change in the optical output P relative to the input power E becomes large in the wavelength filter F₂ with a broad wavelength band. Therefore, an approximation coefficient a₂ of the wavelength filter F₂ is greater than an approximation coefficient a₁ of the wavelength filter F₁. That is, a relation between the approximation coefficients a₁ and a₂ is a₂>a₁. To implement the constant illuminance function, as described above, it is necessary to measure the approximation coefficients related to the change in the optical output P relative to the input power E in advance. Here, the approximation coefficients differ depending on the wavelength bands corresponding to the wavelength filter. Therefore, it is necessary to measure the approximation coefficients for each wavelength filter. If the same approximation coefficient is used between different wavelength filters, accurate power adjustment may not be performed due to an approximation coefficient error and it may be difficult to maintain a target illuminance as the constant illuminance function.

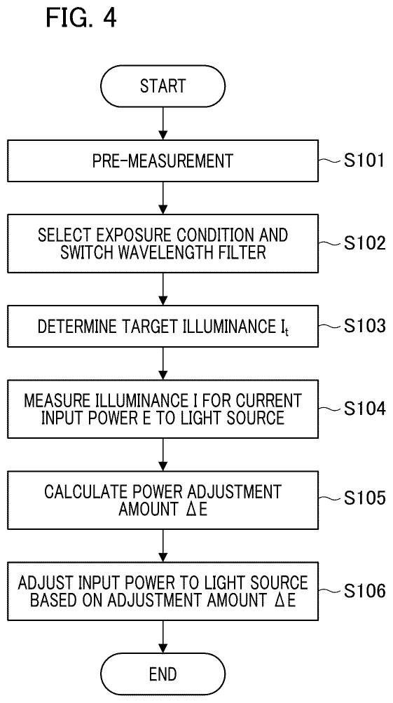

Next, a process of realizing the constant illuminance maintaining function according to the present embodiment will be described below with reference to FIG. 4. FIG. 4 is a flowchart illustrating a process of realizing the constant illuminance maintaining function in the exposure apparatus 100 including a plurality of wavelength filters according to the first embodiment. Each process of FIG. 4 is realized by causing the control unit 21 of the exposure apparatus 100 to execute a program stored in the memory or the like. S is prefixed to each step for notation and the notation of a step will be omitted.

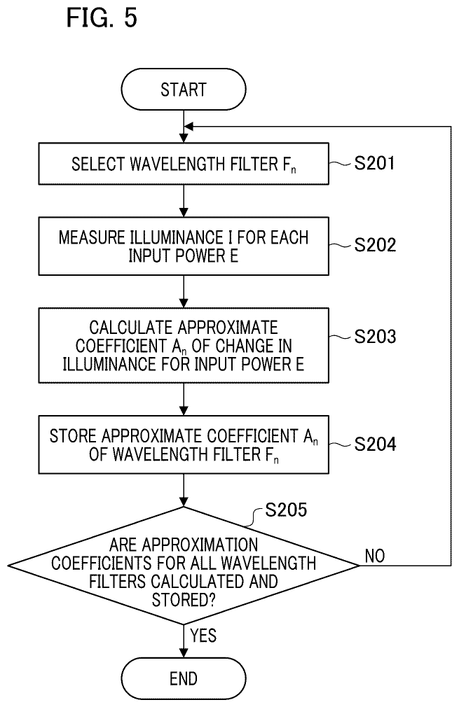

In S101, the control unit 21 performs pre-measurement for the constant illuminance function (measures the approximation coefficient related to the change in the optical output P relative to the input power E in advance). The details of the pre-measurement will be described with reference to FIG. 5.

FIG. 5 is a flowchart illustrating a precondition measurement of the constant illuminance function according to the first embodiment. Each process in FIG. 5 is realized by causing the control unit 21 of the exposure apparatus 100 to execute a program stored in the memory or the like. By prefixing S to each step for notation, the notation of a step is abbreviated.

In S201, the control unit 21 selects a wavelength filter mounted in the exposure apparatus 100 (hereinafter referred to as a wavelength filter Fₙ). When a plurality of wavelength filters are mounted in the exposure apparatus 100 as in the present embodiment, any one wavelength filter Fₙ is selected. When the exposure apparatus 100 according to the present embodiment is given as an example, the control unit 21 selects either the wavelength filter F₁ or the wavelength filter F₂.

In S202, the control unit 21 measures illuminance I measured by the illuminometer 7 while changing the input power E to the light source 1 in the state of the wavelength filter Fₙ selected in S201 by the wavelength filter. In other words, the control unit 21 acquires a measurement result of the illuminance (illuminance for each input power) in accordance with the input power to the light source 1. In the process of S202, it is preferable to acquire the measurement result by changing the input power significantly, but a measurement result of the illuminance is acquired when at least the input power E is changed at two points (two times) or more. An amount of light of each wavelength is changed by causing the control unit 21 to change the input power E to the light source 1.

In S203, the control unit 21 transmits the measurement result of the illuminance I for the input power E to the storage unit 20 and causes the storage unit 20 to store the measurement result. Approximation coefficients Aₙ and Bₙ of a relation formula of the illuminance I for the input power E are calculated. In other words, the control unit 21 calculates the approximation coefficients Aₙ and Bₙ of the relation formula from the measurement result measured in S202. In the present embodiment, the first-order approximation coefficients are given as examples of the approximation coefficients, but higher-order approximation coefficients may also be used. In the present embodiment, the illuminance I in the wavelength filter Fₙ and the approximation coefficients Aₙ and Bₙ of the input power E are expressed as I=Aₙ×E+Bₙ.

In S204, the control unit 21 stores information regarding the approximation coefficient Aₙ calculated in S203 and the wavelength filter Fₙ selected in S101 in the storage unit 20 in association.

In S205, the control unit 21 determines whether the processes from S201 to S204 have been completed on all the wavelength filters mounted on the exposure apparatus 100. In other words, the control unit 21 determines whether the approximation coefficients for all the wavelength filters mounted on the exposure apparatus 100 are calculated and information regarding the calculated approximation coefficients and the wavelength filters are stored in association in the storage unit 20. When the processes from S201 to S204 have not been completed on all the wavelength filters mounted on the exposure apparatus 100 as a result of the determination, the above processes are performed from S201. That is, when there is the wavelength filter for which the approximation coefficients have not been calculated, the above processes are performed on the wavelength filters for which the approximation coefficients are not calculated. Conversely, when the processes from S201 to S204 have been completed on all the wavelength filters mounted on the exposure apparatus 100, the processes illustrated in FIG. 5 end. That is, the process of S101 ends.

When the exposure apparatus 100 according to the present embodiment is given as an example, the control unit 21 first selects the wavelength filter F₁, the approximation coefficients of the input power E and the illuminance I in the wavelength filter F₁ are calculated and are stored in the storage unit 20. Thereafter, after the determination process of S205 is performed, the wavelength filter F₂ is subsequently selected. Thereafter, as in the wavelength filter F₁, the approximation coefficients of the input power E and the illuminance I in the wavelength filter F₂ are calculated and are stored in the storage unit 20. Accordingly, since the approximation coefficients for all the wavelength filters are calculated and the information regarding the wavelength filters and the calculated approximation coefficients are stored in association in the storage unit 20, the processes illustrated in FIG. 5 end.

Subsequently, the process returns to FIG. 4. In S102, the control unit 21 selects the exposure condition of the exposure apparatus 100 and determines the wavelength filter Fₙ to be used. Then, the control unit 21 performs switching the wavelength filter to the determined wavelength filter Fₙ. When the present embodiment is given as an example, the control unit 21 determines a wavelength filter used in accordance with the exposure condition from the wavelength filter F₁ or F₂ and performs switching the wavelength filter to the determined wavelength filter.

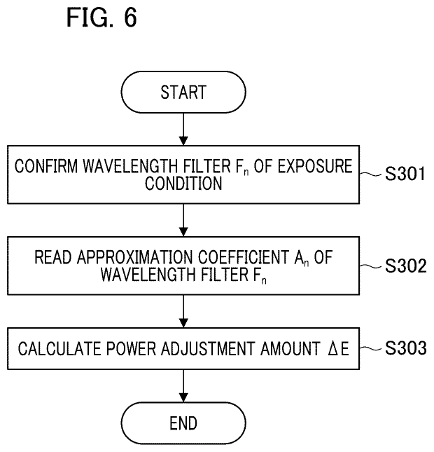

In S103, the control unit 21 determines (sets) a target illuminance Iₜ at the time of applying the constant illuminance function in the wavelength filter Fₙ determined in step S102. The target illuminance Iₜ may be determined for each wavelength filter Fₙ to be used. In S104, the control unit 21 measures the illuminance I in the current input power E. When the current input power E is unclear, the maximum power Eₘₐₓ that can be input to the light source 1 is set and the illuminance I is measured. In S105, the control unit 21 calculates a power adjustment amount ΔE for setting the target illuminance It. The details of S105 will be described with reference to FIG. 6.

FIG. 6 is a flowchart illustrating calculation of a power adjustment amount according to the first embodiment. Each process in FIG. 6 is realized by causing the control unit 21 of the exposure apparatus 100 to execute a program stored in the memory or the like. By prefixing S to each step for notation, the notation of a step is abbreviated.

In S301, the control unit 21 confirms the wavelength filter Fₙ determined based on the exposure condition selected in S102. In S302, the control unit 21 reads the approximation coefficient Aₙ for the wavelength filter Fₙ confirmed in S301 from the storage unit 20.

In S303, the control unit 21 calculates the power adjustment amount ΔE necessary to realize the target illuminance It. The power adjustment amount ΔE is calculated as a power adjustment amount ΔE=I+Aₙ using the approximation coefficient Aₙ for the wavelength filter Fₙ stored in the storage unit 20 and a difference ΔI(=the target illuminance Iₜ—the current illuminance I) between the target illuminance Iₜ and the illuminance I measured in S104. When the calculation of the power adjustment amount ΔE is completed, the process of S105 ends.

Subsequently, referring back to FIG. 4, in S106, the control unit 21 adjusts the input power E to the light source 1 by the power adjustment amount ΔE calculated in S105. In this way, when the control unit 21 controls (adjusting) the power E for the light source 1 in accordance with the wavelength filter Fₙ based on the power adjustment amount ΔE, the exposure apparatus 100 according to the present embodiment can maintain the target illuminance Iₜ. That is, it is possible to maintain the illuminance on the illuminated surface constantly.

The exposure apparatus 100 according to the first embodiment can realize the optimum constant illuminance function in accordance with the wavelength band by acquiring the different approximation coefficient for each wavelength band to be used. Second Embodiment

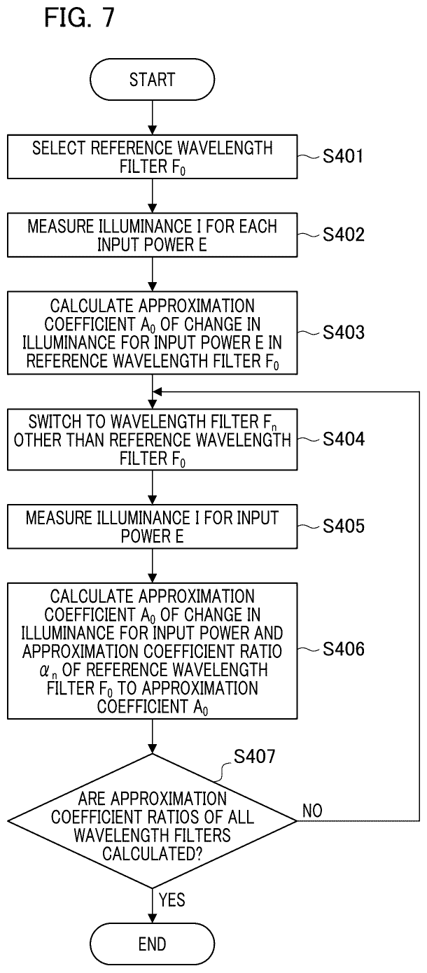

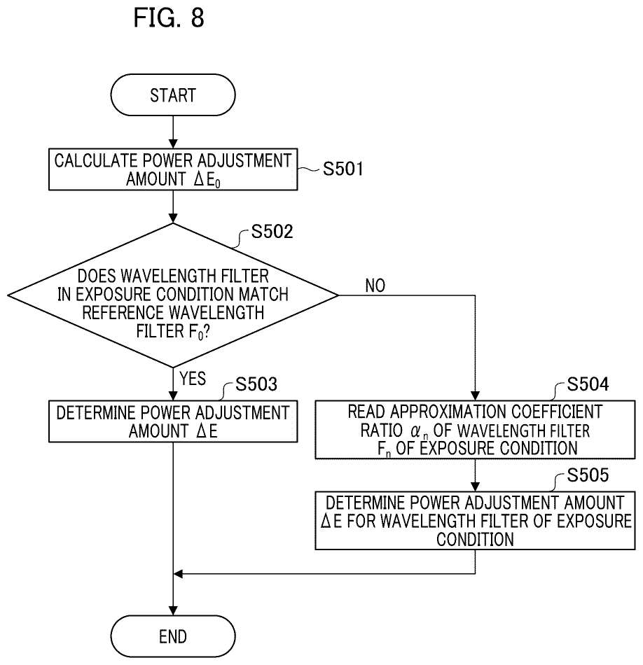

Next, an exposure apparatus 100 according to a second embodiment will be described with reference to FIGS. 7 and 8. The configurations or functions in the exposure apparatus 100 according to the second embodiment are the same as those according to the first embodiment, description thereof will be omitted. A flowchart for realizing a constant illuminance maintaining function according to the second embodiment is similar except for some steps of FIG. 4 according to the first embodiment, but the details of the processes of S101 and S105 are different from those of the first embodiment. Accordingly, a specific process in the second embodiment will be described below.

FIG. 7 is a flowchart illustrating precondition measurement of a constant illuminance function according to the second embodiment. FIG. 8 is a flowchart illustrating calculation of a power adjustment amount according to the second embodiment. In the second embodiment, a flowchart illustrating the details of S101 in FIG. 4 according to the first embodiment is illustrated in FIG. 7 and a flowchart illustrating the details of S105 in FIG. 4 according to the first embodiment is illustrated in FIG. 8.

Hereinafter, the details (a pre-measurement process for the constant illuminance function) of S101 according to the second embodiment will be described with reference to FIG. 7. Each process in FIG. 7 is realized by causing the control unit 21 of the exposure apparatus 100 to execute a program stored in the memory or the like. By prefixing S to each step for notation, the notation of a step is abbreviated. The exposure apparatus 100 according to the second embodiment includes wavelength filters F₁ and F₂ similar to those according to the first embodiment and further includes a reference wavelength filter to be described below. One of the wavelength filters F₁ and F₂ may be set as the reference wavelength filter. In this way, the exposure apparatus 100 according to the second embodiment also includes a plurality of wavelength filters as in the first embodiment. A wavelength band (first wavelength band) of the reference wavelength filter according to the second embodiment is different from wavelength bands of the wavelength filters F₁ and F₂.

In S401, the control unit 21 selects a reference wavelength filter Fₒ among the plurality of wavelength filters. The reference wavelength filter F₀ is one of the plurality of wavelength filters in the exposure apparatus 100. The reference wavelength filter F₀ is set in advance.

In S402, the control unit 21 measures the illuminance I measured by the illuminometer 7 while changing the input power E to the light source 1 in the state of the reference wavelength filter F₀ selected in S401 by the wavelength filter. In other words, the control unit 21 acquires a measurement result of illuminance (illuminance of each input power) in accordance with the input power to the light source 1. In the process of S402, it is preferable to acquire the measurement result by changing the input power significantly, but a measurement result of the illuminance is acquired when at least the input power E is changed at two points (two times) or more.

In S403, the control unit 21 calculates an approximation coefficient A₀ of the illuminance I for the input power E in the reference wavelength filter F₀. Since a method of calculating the approximation coefficient A₀ is the same as that of the first embodiment, description thereof will be omitted. The approximation coefficients according to the second embodiment may be first-order approximation coefficients as in the first embodiment, high-order approximation coefficient may be used. In S404, the control unit 21 selects the wavelength filter Fₙ other than the reference wavelength filter F₀ among the plurality of wavelength filters and performs switching the reference wavelength filter F₀ to the selected wavelength filter. In S405, the control unit 21 measures the illuminance I measured by the illuminometer 7 while changing the input power E to the light source 1 in the state to the wavelength filter switched in S404.

In S406, the control unit 21 calculates the approximation coefficient An of the illuminance I for the input power E to the wavelength filter Fₙ. Further, an approximation coefficient ratio αₙ=Aₙ/A₀ of the reference wavelength filter F₀ calculated in S403 to the approximation coefficient A₀ is calculated using the approximation coefficient An for the input power E in the wavelength filter Fₙ. That is, a ratio of the approximation coefficient Fₙ with no first wavelength band to the reference wavelength filter F₀ that is an optical element with the first wavelength band is calculated. The control unit 21 stores the calculated approximation coefficient ratio αₙ in the storage unit 20.

In S407, the control unit 21 determines whether the calculation of the approximation coefficient ratios of all the wavelength filters mounted on the exposure apparatus 100 is completed. When the calculation of the approximation coefficient ratios of all the wavelength filters mounted on the exposure apparatus 100 is not completed, similar processes are performed from S404. That is, when there is the wavelength filter of which the approximation coefficient ratio an is not calculated, the above similar processes are performed from S404 on the wavelength filter of which the approximation coefficient ratio αₙ is not calculated. Conversely, when the calculation of the approximation coefficient ratios of all the wavelength filters mounted on the exposure apparatus 100 is completed, the process illustrated in FIG. 7 ends. That is, the process of S101 according to the second embodiment ends.

Hereinafter, the details (a process of calculating the power adjustment amount ΔE in S105 according to the second embodiment will be described with reference to FIG. 8. Each process in FIG. 8 is realized by causing the control unit 21 of the exposure apparatus 100 to execute a program stored in the memory or the like. By prefixing S to each step for notation, the notation of a step is abbreviated.

In S501, the control unit 21 calculates a power adjustment amount ΔE₀ using the approximation coefficient A₀ of the reference wavelength filter F₀. The power adjustment amount ΔE₀ of the reference wavelength filter F₀ is expressed as ΔE₀=ΔI+A₀. ΔAI that is a difference in the illuminance I is obtained by the target illuminance Iₜ—the current illuminance I as in the first embodiment.

In S502, the control unit 21 determines whether the wavelength filter in the exposure condition selected in S102 matches the reference wavelength filter F₀. When the wavelength filter in the exposure condition selected in S102 matches the reference wavelength filter F₀ as a result of the determination, the process proceeds to S503. That is, when the reference wavelength filter F₀ is selected as the wavelength filter of the exposure condition, the process proceeds to S503. Conversely, when the wavelength filter in the exposure condition selected in S102 does not match the reference wavelength filter F₀, the process proceeds to S504. That is, when the reference wavelength filter F₀ is not selected as the wavelength filter of the exposure condition, the process proceeds to S504.

In S503, the control unit 21 determines the power adjustment amount ΔE. That is, when the process proceeds to S503, the control unit 21 determines ΔE₀ calculated in S501 as the power adjustment amount ΔE since the reference wavelength filter F₀ is not selected as the wavelength filter of the exposure condition in S502. In this way, in S503, the power adjustment amount ΔE is determined as the power adjustment amount ΔE=the power adjustment amount ΔE₀.

In S504, the control unit 21 confirms the approximation coefficient ratio an of the wavelength filter of the exposure condition for the reference wavelength filter F₀. That is, when the process proceeds to S504, the control unit 21 reads the approximation coefficient ratio an of the approximation coefficient Fₙ of the exposure condition calculated in S406 from the storage unit 20 since reference wavelength filter F₀ is not selected as the wavelength filter of the exposure condition in S502.

In S505, the control unit 21 determines the power adjustment amount ΔE for the wavelength filter Fₙ of the exposure condition. At this time, the power adjustment amount ΔE is expressed as the approximation coefficient ratio Δₙ in the power adjustment amount ΔE=the power adjustment amount ΔE₀/the reference wavelength filter F₀ using power adjustment amount ΔE₀ in the reference wavelength filter F₀ and the approximation coefficient ratio αₙ for the wavelength filter of the exposure condition. In this way, the process of S105 according to the second embodiment ends.

In the case of the second embodiment, not the approximation coefficient of each wavelength filter in the first embodiment but the approximation coefficient ratio of each wavelength filter is stored in the storage unit 20. When the approximation coefficient is changed because of a change in the light source 1 over time, it is necessary to measure the approximation coefficient again since the approximation coefficients for all the wavelength filters are stored directly in the first embodiment. Here, in the second embodiment, the relation of the approximation coefficient of each wavelength filter is stored. Therefore, when only the approximation coefficient of the reference wavelength is measured again, it is not necessary to measure the approximation coefficient of another wavelength filter again. Therefore, it is possible to shorten a calculation load or a time.

As described above, in the exposure apparatus 100 according to the second embodiment, in addition to similar advantages to those of the first embodiment, it is possible to shorten a calculation load or a time not by measuring the approximation coefficient of another wavelength filter again but by measuring only the approximation coefficient of the reference wavelength again.

### Embodiment of Method of Manufacturing Product

A method of a manufacturing a product according to an embodiment of the present invention is appropriate for manufacturing, for example, a product such as a semiconductor element, a flat panel display, a liquid crystal display element, or a MEMS. The manufacturing method includes a step of exposing a substrate to which a photosensitizer is applied using the above-described exposure apparatus 100 and a step of developing the exposed photosensitizer. A circuit pattern is formed on the substrate by performing an etching step, an ion implementing step, and the like on the substrate using a pattern of the developed photosensitizer as a mask. As subsequent steps, dicing (processing) is performed on the substrate on which the circuit pattern is formed, and chip mounting, bonding, and an inspection step are performed. The manufacturing method can include another known steps (oxidizing, film forming, depositing, doping, flattening, resist peeling, and the like). The method of manufacturing a product according to the present embodiment is advantageous in at least one of performance, quality, productivity, and production cost of a product compared to the related art.

### Other Embodiments

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)?), a flash memory device, a memory card, and the like.

This application claims the benefit of Japanese Patent Application No. 2024-53419, filed Mar. 28, 2024, which is hereby incorporated by reference wherein in its entirety.

What is claimed is:

1. An exposure apparatus comprising:
an illumination optical system including a plurality of optical elements changing a wavelength band of light from a light source and configured to illuminate an illuminated surface with light of which a wavelength band has been changed by one of the plurality of optical elements; and
a control unit configured to control input power to the light source using a correction value corresponding to a relation of a change in illuminance to the input power
wherein the control unit uses different correction values for the plurality of optical elements.

2. The exposure apparatus according to claim 1, wherein the correction value is an approximation coefficient indicating the change in illuminance of the illuminated surface to the input power to the light source.

3. The exposure apparatus according to claim 1, wherein the control unit calculates the correction value based on a measurement result obtained by measuring the illuminance while changing the input power to the light source for each of the optical elements.

4. The exposure apparatus according to claim 3, wherein the control unit calculates the correction value from an approximation formula obtained from measurement results obtained by measuring the illuminance on the illuminated surface at two or more points.

5. The exposure apparatus according to claim 1, wherein the illuminance is illuminance of the illuminated surface and a surface at a position conjugating to irradiation.

6. The exposure apparatus according to claim 1,
wherein the plurality of optical elements are disposed inside the illumination optical system, and
wherein the control unit switches between the plurality of optical elements in accordance with a predetermined exposure condition.

7. The exposure apparatus according to claim 1, wherein the control unit changes the input power to the light source to change an amount of light of each wavelength.

8. The exposure apparatus according to claim 1, wherein the plurality of optical elements change a wavelength band of the light so that a central wavelength of the wavelength band is identical and a wavelength bandwidth is different.

9. The exposure apparatus according to claim 1, wherein the control unit calculates a power adjustment amount for achieving target illuminance and adjusts the input power to the light source based on the power adjustment amount.

10. The exposure apparatus according to claim 9, wherein the control unit calculates the power adjustment amount based on the correction value and a difference between the target illuminance and current illuminance.

11. The exposure apparatus according to claim 1, wherein the control unit calculates a ratio of the correction value of an optical element with a wavelength band other than a first wavelength band to the correction value of an optical element with the first wavelength band.

12. The exposure apparatus according to claim 1, further comprising a storage unit configured to store the correction value.

13. A method of controlling an exposure apparatus, the method comprising:
illuminating, by an illumination optical system including a plurality of optical elements changing a wavelength band of light from a light source, an illuminated surface with light of which a wavelength band has been changed by one of the plurality of optical elements; and
controlling input power to the light source using a correction value corresponding to a relation of a change in illuminance to the input power to the light source to maintain constant illuminance on the illuminated surface,
wherein, in the controlling, different correction values for the plurality of optical elements are used.

14. A method of manufacturing a product, the method comprising:
exposing a substrate using an exposure apparatus;
developing the exposed substrate; and
manufacturing a product from the developed substrate,
wherein the exposure apparatus includes
an illumination optical system that includes a plurality of optical elements changing a wavelength band of light from a light source and illuminates an illuminated surface with light of which a wavelength band has been changed by one of the plurality of optical elements, and
a control unit that controls input power to the light source using a correction value corresponding to a relation of a change in illuminance to the input power to the light source to maintain constant illuminance on the illuminated surface, and
wherein the control unit uses different correction values for the plurality of optical elements.
